(19) United States
(12) Patent Application Publication
(10) Pub. No.: US 2020/0357983 A1
(43) Pub. Date: Nov. 12, 2020

(54) Magnetic tunnel junction reference layer, magnetic tunnel junctions and magnetic random access memory

(71) Applicant: BEIHANG UNIVERSITY, Beijing (CN)

(72) Inventors: Weisheng Zhao, Beijing (CN); Houyi Cheng, Beijing (CN); Kaihua Cao, Beijing (CN); Gefei Wang, Beijing (CN)

(73) Assignee: BEIHANG UNIVERSITY

(21) Appl. No.: 16/936,451

(22) Filed: Jul. 23, 2020

(30) Foreign Application Priority Data
Apr. 26, 2020 (CN) 202010337131.4

(51) Int. Cl. H01L 43/08; H01L 43/02; H01L 43/10; H01L 27/22

(52) U.S. Cl. CPC H01L 43/08; H01L 27/222; H01L 43/10; H01L 43/02

(57) ABSTRACT

A magnetic tunnel junction reference layer, magnetic tunnel junctions and a magnetic random access memory are provided, wherein the magnetic tunnel junction reference layer includes: an antiferromagnetic structure layer, which comprises a plurality of stacked metal magnetic layer units, wherein each of the metal magnetic layer units comprises a spacer layer and a magnetic layer on a surface of the spacer layer. The present invention forms a synthetic antiferromagnetic structure through multilayer stack of the metal spacer layer and the magnetic layer, so as to increase thermal stability of the magnetic tunnel junction reference layer with perpendicular magnetic anisotropy and reduce design complexity as well as cost of the film layers. The present invention forms a multilayer film structure without oxides, which has strong perpendicular magnetic anisotropy, high thermal stability, simple film layer, and low cost, thereby promoting large-scale use of the magnetic memory.

### CROSS REFERENCE OF RELATED APPLICATION

The present invention claims priority under 35 U.S.C. 119(a-d) to CN 202010337131.4, filed Apr. 26, 2020.

### BACKGROUND OF THE PRESENT INVENTION

### Field of Invention

The present invention relates to a technical field of magnetic random access memory, and more particularly to a magnetic tunnel junction reference layer, magnetic tunnel junctions and a magnetic random access memory.

### Description of Related Arts

Magnetic random access memory is non-volatile, and has low power consumption as well as unlimited read and write times. Spin transfer torque based magnetic random access memory (STT-MRAM) has reached a good compromise in speed, area, write times and power consumption, thus being considered by the industry as an ideal device for building the next generation of non-volatile cache. Magnetic tunnel junction (MTJ) is a core storage part of the STT-MRAM, which is mainly composed of two magnetic layers and a tunneling barrier layer. The two magnetic layers comprise a reference layer whose magnetization direction is fixed and a free layer whose magnetization direction can be the same as or opposite to that of the reference layer. When the magnetization direction of the free layer is parallel to the reference layer, the MTJ is in a low resistance state, otherwise the MTJ is in a high resistance state. Such different resistance states can be used to represent “0” and “1” of binary data. The magnetic memory changes the magnetization direction of the free layer through the spin transfer torque (STT) to write “0” and “1”. If device size is decreased, the magnetic tunnel junctions with in-plane magnetic anisotropy will suffer severe marginal effects and affect storage stability. Therefore, magnetic tunnel junctions with perpendicular magnetic anisotropy (p-MTJs) are widely used in STT-MRAM. In addition, due to the processing (such as subsequent process) requirements, the magnetic tunnel junction needs to withstand a high annealing temperature (usually 400° C.), so the reference layer needs to be stable at the high annealing temperature to avoid read and write failures. Therefore, a stable magnetization direction of the reference layer is of great significance to the STT-MRAM. The conventional reference layer mainly adopts two structures, one is to pin the magnetization direction of the reference layer through an antiferromagnetic material, and the other is to form a synthetic antiferromagnetic structure through a multilayer film to pin the magnetization direction of the reference layer, but both have their own defects.

### SUMMARY OF THE PRESENT INVENTION

To overcome the above defects, an object of the present invention is to provide a magnetic tunnel junction reference layer, magnetic tunnel junctions and a magnetic random access memory.

Firstly, the present invention provides a magnetic tunnel junction reference layer, comprising:

an antiferromagnetic structure layer, which comprises a plurality of stacked metal magnetic layer units, wherein each of the metal magnetic layer units comprises a spacer layer and a magnetic layer on a surface of the spacer layer.

Preferably, the magnetic tunnel junction reference layer further comprises:

a first oxide barrier layer on a first surface of the antiferromagnetic structure layer;

a second oxide barrier layer on a second surface of the antiferromagnetic structure layer facing away from the first oxide barrier layer; and

a first buffer layer located on a surface of the second oxide barrier layer facing away from the antiferromagnetic structure layer.

Preferably, the magnetic tunnel junction reference layer further comprises:

a second buffer layer on a surface of the first buffer layer facing away from the second oxide barrier layer; and

a substrate on a surface of the second buffer layer facing away from the first buffer layer.

Preferably, the magnetic tunnel junction reference layer further comprises:

a capping layer on a surface of the first oxide barrier layer facing away from the antiferromagnetic structure layer.

Preferably, the first buffer layer and/or the spacer layer is selected from the group consisting of tantalum, tungsten, molybdenum, chromium, niobium, and ruthenium.

Preferably, the magnetic layer is selected from the group consisting of CoFeB, CoFe, FeB, Co, Fe, and Heusler alloys.

Preferably, the first oxide barrier layer and the second oxide barrier layer are selected from the group consisting of magnesium oxide, aluminum oxide, magnesium aluminum oxide, hafnium oxide, and tantalum oxide.

Preferably, a thickness of the spacer layer is 0.1-1 nm.

Secondly, the present invention provides a magnetic tunnel junction, comprising a magnetic tunnel junction reference layer as mentioned above.

Thirdly, the present invention provides the magnetic random access memory, comprising a plurality of storage units, wherein each of the storage units comprises a magnetic tunnel junction as mentioned above.

Beneficial effects of the present invention are as follows:

The present invention provides a magnetic tunnel junction reference layer, magnetic tunnel junctions and a magnetic random access memory. A synthetic antiferromagnetic structure is formed through multilayer stack of the metal spacer layer and the magnetic layer, so as to increase thermal stability of the reference layer in the perpendicular magnetic anisotropy based magnetic tunnel junctions and reduce design complexity as well as cost of the thin films. The present invention forms a multilayer film structure without oxides, which has strong perpendicular magnetic anisotropy, high thermal stability, simple film structure, and low cost, thereby promoting large-scale use of the magnetic memory.

### BRIEF DESCRIPTION OF THE DRAWINGS

Drawings for describing embodiments or prior art will be briefly introduced below to more clearly explain the embodiments of the present invention or technical solutions in prior art. Obviously, the drawings in the following description are only some embodiments of the present invention. For those of ordinary skill in the art, other drawings can be obtained based on these drawings without paying any creative work.

FIG. 1 is a structural view of a magnetic tunnel junction in the prior art.

FIG. 2a is a first structural view of a magnetic tunnel junction reference layer in the prior art.

FIG. 2b a second structural view of a magnetic tunnel junction reference layer in the prior art.

FIG. 3 is a third structural view of a magnetic tunnel junction reference layer in the prior art.

FIG. 4 is a structural view of a magnetic tunnel junction reference layer in an embodiment of the present invention.

FIG. 5 is a first specific structural view of the magnetic tunnel junction reference layer in the embodiment of the present invention.

FIG. 6 is a second specific structural view of the reference layer of the magnetic tunnel junction in the embodiment of the present invention.

FIG. 7 is a third specific structural view of the reference layer of the magnetic tunnel junction in the embodiment of the present invention.

FIG. 8 is a fourth specific structural view of the reference layer of the magnetic tunnel junction in the embodiment of the present invention.

FIG. 9 is a fifth specific structural view of the reference layer of the magnetic tunnel junction in the embodiment of the present invention.

FIG. 10 is a sixth specific structural view of the specific structure of the magnetic tunnel junction reference layer in the embodiment of the present invention.

FIG. 11 a structural view of a spin valve in the prior art.

FIG. 12 is a structural view of a spin valve in an embodiment of the present invention.

FIG. 13 is a structural view of a racetrack memory in an embodiment of the present invention.

### DETAILED DESCRIPTION OF THE PREFERRED EMBODIMENT

The technical solutions in embodiments of the present invention will be described clearly and completely in conjunction with the drawings for the embodiments of the present invention. Obviously, the described embodiments are only a part of all embodiments of the present invention. Based on these embodiments of the present invention, all other embodiments obtained by a person of ordinary skill in the art without creative effort should fall within the protection scope of the present invention.

Conventional reference layers mainly adopt two structures, one is to pin the magnetization direction of the reference layer through an antiferromagnetic material, and the other is to form a synthetic antiferromagnetic structure through a multilayer film to pin the magnetization direction of the reference layer, but both have their own defects.

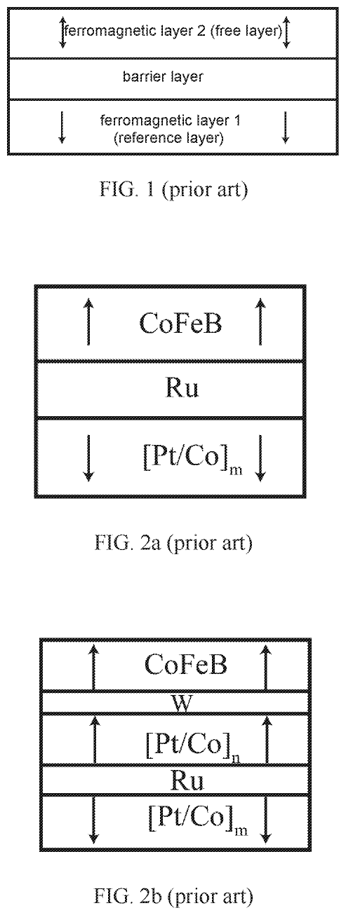

FIG. 1 is a typical structural view of an MTJ, wherein the unidirectional downward black arrow in the reference layer represents that the magnetization direction of the reference layer is fixed downward and perpendicular to the magnetic memory cell plane; and the bidirectional black arrow in the magnetic layer represents that the magnetization direction of the magnetic layer can be changed to be parallel or antiparallel to the magnetization direction of the reference layer. When the magnetization directions of the two magnetic layers are parallel, the MTJ is in a low resistance state, otherwise the MTJ is in a high resistance state.

FIG. 2a is a first structural view of a magnetic tunnel junction reference layer in the prior art, and FIG. 2b a second structural view of a magnetic tunnel junction reference layer in the prior art. The magnetic tunnel junction reference layer is formed by a synthetic antiferromagnetic (SAF) layer and a magnetic layer. The magnetic layer is made of CoFeB, CoFe or the like. The synthetic antiferromagnetic layer realizes antiferromagnetic coupling through Pt/Co multilayer film to pin the magnetic layer to maintain a stable magnetization direction of the reference layer. To ensure a large coercive force difference between the reference layer and the free layer, a coercive field is increased by stacking multiple Pt/Co layers. The spacer layer material is Ru and other metals to achieve antiferromagnetic coupling. Using the Pt/Co multilayer film to construct the reference layer and forming antiferromagnetic coupling through the Pt/Co multilayer film can pin the magnetization direction of the reference layer. There are two main ways to construct the reference layer through the Pt/Co multilayer film; as shown in FIG. 2a, inserting a spacer material Ru between the Pt/Co multilayer film and the magnetic layer can realize the antiferromagnetic coupling of the two layers; or as shown in FIG. 2b, the magnetization direction of the reference layer is further pinned through constructing a synthetic antiferromagnetic structure by two Pt/Co layers.

However, a pinned layer formed by the antiferromagnetic coupling through the P/Co multilayer film can maintain the magnetization direction of the reference layer, but such method has a high cost and increases system complexity. In addition, thermal stability of Pt/Co in such system is not high, which limits the processing.

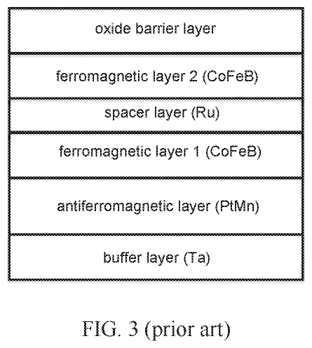

FIG. 3 is a structural view of a magnetic tunnel junction in the prior art, wherein the magnetization direction of the reference layer is fixed by combining the antiferromagnetic layer and the synthetic antiferromagnetic layer. Referring to FIG. 3, the bottom magnetic layer of the synthetic antiferromagnetic layer in magnetic tunnel junctions is pinned by an antiferromagnetic material (such as PtMn). Then Ru or other materials is inserted for coupling of the two layers of the synthetic antiferromagnetic, in such a manner that the magnetic layer close to the barrier will have a fixed magnetization direction. However, accurate data reading and writing require a large coercive force difference between the reference layer and the free layer, while the coercive force difference of such method is relatively small. As a result, fault tolerance of the magnetic memory is not strong. In addition, the antiferromagnetic pinned layer (such as PtMn) is relatively active, which is easy to diffuse at a high annealing temperature and damage the magnetic layer, and the cost is high.

Referring to the various problems such as complicated design of the conventional magnetic tunnel junction reference layer, weak thermal stability and high cost, the present invention provides a multilayer film structure with high thermal stability and low cost, which overcomes the defects of the prior art. The present invention has advantages of simple and reliable design, high thermal stability, low cost and so on.

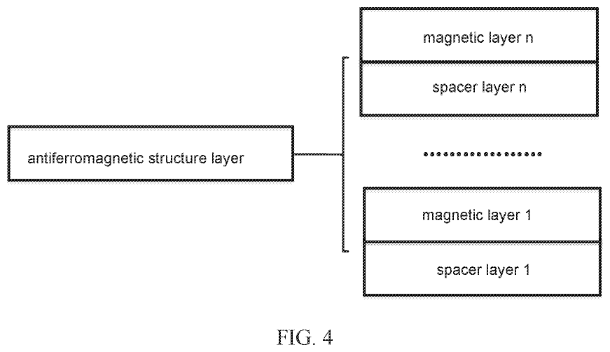

Referring to FIG. 4, a magnetic tunnel junction reference layer in an embodiment of the present invention is shown, comprising: an antiferromagnetic structure layer, which comprises a plurality of stacked metal magnetic layer units, wherein each of the metal magnetic layer units comprises a spacer layer and a magnetic layer on a surface of the spacer layer.

It should be noted that the above-mentioned surface of the spacer layer refers to a top surface or a bottom surface of the spacer layer. Furthermore, those skilled in the art can understand that each metal magnetic layer unit should be completely identical in structure, which means in all the metal magnetic layer units, the magnetic layer is located on the top surface of the spacer layer, or on the bottom surface of the spacer layer. When multiple metal magnetic layer units are stacked, the macro structure is a spacer layer, a magnetic layer, a spacer layer, a magnetic layer, and so on.

The present invention provides the magnetic tunnel junction reference layer, wherein a synthetic antiferromagnetic structure is formed by the metal spacer layer and the magnetic layer, so as to increase thermal stability of the reference layer of p-MTJs and reduce design complexity as well as cost of the film layers. The present invention forms a multilayer film structure without oxides, which has strong perpendicular magnetic anisotropy, high thermal stability, simple film layer, and low cost, thereby promoting large-scale use of the magnetic memory.

Specifically, as shown in FIG. 5, the antiferromagnetic structure layer comprises multiple spacer layers and multiple magnetic layers which are alternately arranged in pairs. Referring to FIG. 5, from bottom to top, there are a spacer layer 1, a magnetic layer 1, a spacer layer 2, a magnetic layer 2, . . . , a spacer layer N, and a magnetic layer N, which form the above-mentioned antiferromagnetic structure layer, wherein N is a positive integer greater than 1.

Also, in FIG. 5, a material of the magnetic layer 1 . . . . , and the magnetic layer N is selected from the group consisting of CoFeB, CoFe, FeB, Co, Fe, and Heusler alloys; a thickness of the magnetic layer is 0.2-2 nm. The thickness and material of different layers may be different.

The spacer layer 1, . . . , and the spacer layer N are made of metal, which may be selected from, but not limited to, molybdenum (Mo), chromium (Cr), niobium (Nb), vanadium (V), or their alloys. A thickness is 0.1-1 nm.

A buffer layer 1 (a first buffer layer) is made of metal, which can be selected from, but not limited to, tantalum (Ta), tungsten (W), molybdenum (Mo), chromium (Cr), niobium (Nb), ruthenium (Ru) or their alloys. Preferably, a thickness is 0.2-5 nm.

A first oxide barrier layer is selected from the group consisting of magnesium oxide, aluminum oxide, magnesium aluminum oxide, hafnium oxide, and tantalum oxide. Preferably, the first oxide barrier layer is made of magnesium oxide (MgO) with a thickness of 0.2-5 nm.

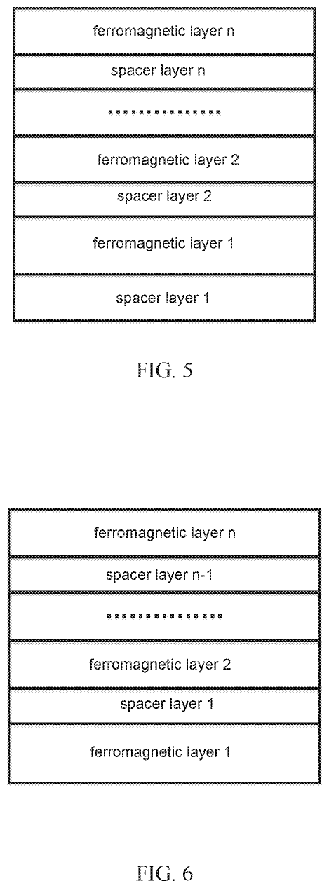

As shown in FIG. 6, the antiferromagnetic structure layer comprises multiple spacer layers and multiple magnetic layers which are alternately arranged in pairs. Referring to FIG. 6, from bottom to top, there are a magnetic layer 1, a spacer layer 1, a magnetic layer 2, . . . , a spacer layer N−1, and a magnetic layer N, which all together form the above-mentioned antiferromagnetic structure layers, wherein N is a positive integer greater than 1.

In some embodiments not shown in the drawings, the magnetic tunnel junction reference layer of the present invention further comprises: a first oxide barrier layer on a first surface of the antiferromagnetic structure layer; a second oxide barrier layer on a second surface of the antiferromagnetic structure layer facing away from the first oxide barrier layer; and a first buffer layer located on a surface of the second oxide barrier layer facing away from the antiferromagnetic structure layer. In addition, in the embodiments not shown in the drawings, the magnetic tunnel junction reference layer of the present invention further comprises: a second buffer layer on a surface of the first buffer layer facing away from the second oxide barrier layer; and a substrate on a surface of the second buffer layer facing away from the first buffer layer.

Furthermore, in another embodiment of the present invention, the magnetic tunnel junction reference layer of the present invention further comprises: a capping layer on a surface of the first oxide barrier layer facing away from the antiferromagnetic structure layer.

Also, in FIG. 6, the buffer layer 1 (the first buffer layer) is made of metal, which can be selected from, but not limited to, tantalum (Ta), tungsten (W), molybdenum (Mo), chromium (Cr), niobium (Nb), ruthenium (Ru) or their alloys. Preferably, a thickness is 0.2-5 nm.

A material of the magnetic layer 1, . . . , and the magnetic layer N is selected from the group consisting of CoFeB, CoFe, FeB, Co, Fe, and Heusler alloys; a thickness of the magnetic layer is 0.2-2 nm. The thickness and material of different layers may be different.

The spacer layer 1, . . . , and the spacer layer N−1 are made of metal, which may be selected from, but not limited to, molybdenum (Mo), chromium (Cr), niobium (Nb), vanadium (V), or their alloys. A thickness is 0.1-1 nm.

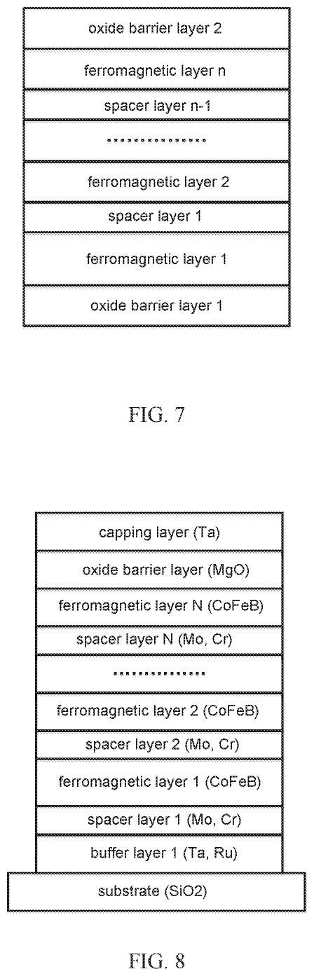

As shown in FIG. 7, in the embodiment containing the second oxide barrier layer, from bottom to top, there are an oxide barrier layer 1, a magnetic layer 1, a spacer layer 1, . . . , a spacer layer N−1, and a magnetic layer N.

The oxide barrier layer 1 (the first oxide barrier layer) and the oxide barrier layer 2 (the second oxide barrier layer) are selected from the group consisting of magnesium oxide, aluminum oxide, magnesium aluminum oxide, hafnium oxide, and tantalum oxides. Preferably, magnesium oxide (MgO) is adopted, and a thickness is 0.2-5 nm.

A material of the magnetic layer 1, . . . , and the magnetic layer N is selected from the group consisting of CoFeB. CoFe. FeB, Co, Fe, and Heusler alloys; a thickness of the magnetic layer is 0.2-2 nm. The thickness and material of different layers may be different.

The spacer layer 1, . . . , and the spacer layer N−1 are made of metal, which may be selected from, but not limited to, molybdenum (Mo), chromium (Cr), niobium (Nb), vanadium (V), or their alloys. A thickness is 0.1-1 nm.

The buffer layer is made of metal, which can be selected from, but not limited to, tantalum (Ta), tungsten (W), molybdenum (Mo), chromium (Cr), niobium (Nb), ruthenium (Ru) or their alloys. Preferably, a thickness is 0.2-5 nm.

A film structure refers to a stack structure with layered films, which uses magnetron sputtering, molecular beam epitaxy, pulsed laser deposition or atomic layer deposition to grow the materials of each layer on the substrate or other multilayer films from bottom to top, and then nano-device processing techniques such as photolithography and etching are performed to prepare a nano-junction. A cross-sectional area of each thin layer is basically the same, and a shape thereof is generally a circle, an ellipse, a square, or a rectangle.

The buffer layer (comprising the first buffer layer and the second buffer layer) refers to a layer of metal, metal alloy, or oxide material under the magnetic layer or the oxide barrier layer, which reduces surface roughness, promotes crystallization of the multilayer film, improves an interface state of the multilayer film, and adjusts an effect of perpendicular magnetic anisotropy.

The oxide barrier layer refers to a metal oxide used to enhance spin electron polarizability and provide tunneling channel, so as to increase a tunneling magnetoresistance effect. Magnesium oxide (MgO) is usually used.

The magnetic layer refers to a metal layer formed by a ferromagnetic material. At a room temperature (20 to 25 degrees Celsius), an easy magnetization axis of the thin layer is perpendicular to a direction of a film plane. The magnetic layer can be used as the free layer and the reference layer in the magnetic tunnel junction, which usually adopts the ferromagnetic material, but other metals and alloys with magnetic capabilities are also applicable. If the ferromagnetic material is used, the magnetic layer is called a ferromagnetic layer.

The spacer layer refers to a metal or metal alloy material between two magnetic layers. The spacer layer adds interface between the metal and the ferromagnetic materials, in such a manner that the easy magnetization axis can be kept perpendicular to the film plane while the thickness of the magnetic layer is increased. Spin-orbit coupling at the interface can increase the interfacial perpendicular magnetic anisotropy, reduce a magnetic damping coefficient, and reduce a critical flip current. The spacer layer allows the two magnetic layers to be coupled together through a Ruderman-Kittel-Kasuya-Yoshida (RKKY) effect. By controlling the thickness of the spacer layer, the ferromagnetic coupling or antiferromagnetic coupling can be achieved, and coupling strength can be controlled. At the same time, the coercive field can also be increased.

The substrate may adopt silicon, glass or other substances with stable chemical properties and a flat surface.

The capping layer can adopt tantalum (Ta), ruthenium (Ru), platinum (Pt), silicon dioxide (SiO₂) and other metal materials and non-metallic materials. A thickness of the capping layer is generally 1-100 nm.

Common element ratios of CoFeB may be Co₂₀Fe₆₀B₂₀, Co₄₀Fe₄₀B₂₀ or Co₆₀Fe₂₀B₂₀, etc. Numbers here represent possible percentages of the elements, and not intend to be limiting.

Common element ratios of FeB may be Fe₈₀B₂₀, etc. Numbers here represent possible percentages of the elements, and not intend to be limiting.

Common element ratios of CoFe may be Co₅₀Fe₅₀, Co₂₀Fe₈₀, Co₈₀Fe₂₀, etc. Numbers here represent possible percentages of the elements, and not intend to be limiting.

The Heusler alloy may be cobalt iron aluminum (Co₂FeAl), cobalt manganese silicon (Co₂MnSi) and other materials, wherein element types and element ratios can be changed.

Core ideas of the present invention will be further illustrated with the following embodiments.

In one embodiment, the buffer layer 1, the spacer layer 1, the magnetic layer 1, the spacer layer 2, the magnetic layer 2, . . . , the spacer layer N, the magnetic layer N and the oxide barrier layer are deposited on a thermally oxidized silicon substrate from bottom to top, and a capping layer is deposited on the oxide barrier layer, as shown in FIG. 8. Finally, photolithography, etching and other processes are performed, and a cross section is circular.

Among them, the material of the buffer layer 1 is Ta or Ru, the thickness is 5 nm. The material of the magnetic layer 1, . . . , and the magnetic layer N is CoFeB, the thickness is 1 nm. The material of the spacer layer 1, . . . , and the spacer layer N is Mo or Cr, the thickness is 0.8 nm. The material of the oxide barrier layer is MgO, the thickness is 1 nm. The material of the capping layer is Ta, the thickness is 5 nm. With the foregoing structure, the antiferromagnetic coupling of each magnetic layer can be achieved. Furthermore, since the interface at the Mo(Cr)/CoFeB surface has strong perpendicular magnetic anisotropy, a relatively strong perpendicular magnetic anisotropy can be maintained without MgO. By controlling the thickness of the spacer layer to 0.8 nm, a strong antiferromagnetic coupling can be obtained. Multilayer stacking can also enhance the coercive field, which is helpful to distinguish the reference layer from the free layer, and reduce read and write error rates. In addition, the structure has less diffusion and has stronger thermal stability, so as to reduce a cross-sectional area of the multilayer film within a certain range and increase magnetic storage density.

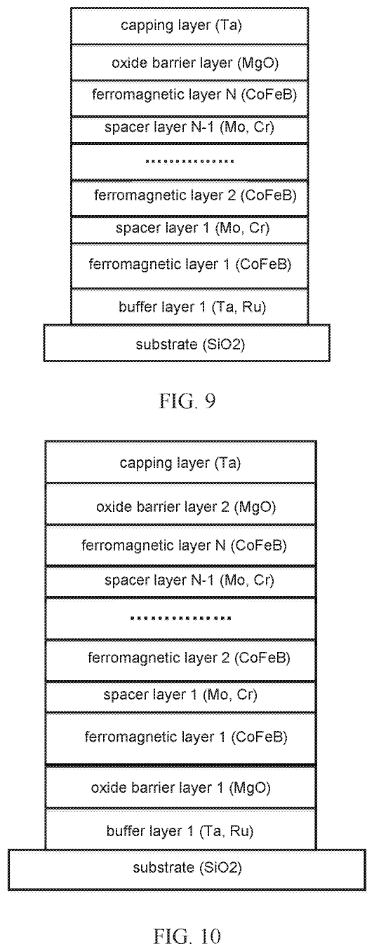

In another embodiment, the buffer layer 1, the magnetic layer 1, the spacer layer 1, the magnetic layer 2, . . . , the spacer layer N−1, the magnetic layer N and the oxide barrier layer are deposited on a thermally oxidized silicon substrate from bottom to top, and a capping layer is deposited on the oxide barrier layer, as shown in FIG. 9. Finally, photolithography, etching and other processes are performed, and a cross section is circular.

Among them, the material of the buffer layer 1 is Ta or Ru, the thickness is 5 nm. The material of the magnetic layer 1, . . . , and the magnetic layer N is CoFeB, the thickness is 1 nm. The material of the spacer layer 1, . . . , and the spacer layer N is Mo or Cr, the thickness is 0.8 nm. The material of the oxide barrier layer is MgO, the thickness is 1 nm. The material of the capping layer is Ta, the thickness is 5 nm. With the foregoing structure, the antiferromagnetic coupling of each magnetic layer can be achieved. Furthermore, since the interface at the Mo(Cr)/CoFeB surface has strong perpendicular magnetic anisotropy, a relatively strong perpendicular magnetic anisotropy can be maintained without MgO. By controlling the thickness of the spacer layer to 0.8 nm, a strong antiferromagnetic coupling can be obtained. Multilayer stacking can also enhance the coercive field, which is helpful to distinguish the reference layer from the free layer, and reduce read and write error rates. At the same time, the thickness of the buffer layer and the material can be controlled to adjust the interface to enhance the perpendicular magnetic anisotropy. In addition, the structure has less diffusion and has stronger thermal stability, so as to reduce a cross-sectional area of the multilayer film within a certain range and increase magnetic storage density.

In yet another embodiment, the buffer layer 1, the oxide barrier layer 1, the magnetic layer 1, the spacer layer 1, the magnetic layer 2, . . . , the spacer layer N−1, the magnetic layer N and the oxide barrier layer 2 are deposited on a thermally oxidized silicon substrate from bottom to top, and a capping layer is deposited on the oxide barrier layer, as shown in FIG. 10. Finally, photolithography, etching and other processes are performed, and a cross section is circular.

Among them, the material of the buffer layer 1 is Ta or Ru, the thickness is 5 nm. The material of the magnetic layer 1, . . . , and the magnetic layer N is CoFeB, the thickness is 1 nm. The material of the spacer layer 1, . . . , and the spacer layer N−1 is Mo or Cr, the thickness is 0.8 nm. The material of the oxide barrier layer is MgO, the thickness is 1 nm. The material of the capping layer is Ta, the thickness is 5 nm.

In the above embodiments, there are two CoFeB/MgO interfaces and several CoFeB/Mo(Cr) interfaces. These interfaces can produce strong spin-orbit coupling effects and can provide strong perpendicular magnetic anisotropy. At the same time, the CoFeB/Mo(Cr) interface is relatively stable and can maintain high thermal stability. Strong antiferromagnetic coupling of the magnetic layers can be achieved By controlling the thickness of the spacer layer Mo(Cr), and the coercive field can be enhanced by multi-layer stacking, which is conducive to enhancing the tunneling magnetic resistance. In addition, since such structure has strong thermal stability, the cross-sectional area of the multilayer film can be reduced within a certain range to increase the magnetic storage density.

Based on the same inventive concept, the present invention also provides an embodiment of a magnetic tunnel junction, which comprises the magnetic tunnel junction reference layer according to the above embodiments. Those skilled in the art may understand that, in some embodiments, the magnetic tunnel junction also comprises the free layer, which will not be repeated here.

The present invention provides the magnetic tunnel junction, wherein a synthetic antiferromagnetic structure is formed by the metal spacer layer and the magnetic layer, so as to increase thermal stability of the reference layer of p-MTJs and reduce design complexity as well as cost of the film layers. The present invention forms a multilayer film structure, which has strong perpendicular magnetic anisotropy, high thermal stability, simple film structure, and low cost, thereby promoting large-scale use of the magnetic memory.

Based on the same inventive concept, the present invention also provides an embodiment of a magnetic random access memory, which comprises a plurality of storage units, wherein each of the storage units comprises the above magnetic tunnel junction, and the magnetic tunnel junction comprises the magnetic tunnel junction reference layer according to the above embodiments. Those skilled in the art may understand that, in some embodiments, the magnetic tunnel junction also comprises the free layer, which will not be repeated here.

The present invention provides the magnetic random access memory, wherein a synthetic antiferromagnetic structure is formed by the metal spacer layer and the magnetic layer, so as to increase thermal stability of the reference layer of p-MTJs and reduce design complexity as well as cost of the film layers. The present invention forms a multilayer film structure, which has strong perpendicular magnetic anisotropy, high thermal stability, simple film structure, and low cost, thereby promoting large-scale use of the magnetic memory.

Based on the same inventive concept, the present invention also provides an embodiment of a spin valve, which comprises a first magnetic layer, a non-magnetic spacer layer, a second magnetic layer and an antiferromagnetic structure layer, wherein the antiferromagnetic structure layer comprises a plurality of stacked metal magnetic layer units, wherein each of the metal magnetic layer units comprises a spacer layer and a magnetic layer on a surface of the spacer layer.

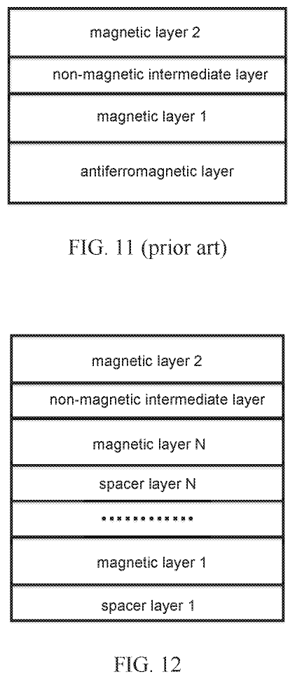

A conventional spin valve structure is mainly composed of four layers, that is, a magnetic layer 1, a non-magnetic spacer layer, a magnetic layer 2, and an antiferromagnetic layer, as shown in FIG. 11. The antiferromagnetic layer has strong uniaxial magnetic anisotropy, which can pin the magnetic layer 2 in the easy magnetization direction. The magnetic layer 2 is called a free layer, whose magnetization direction can be changed by applying an external magnetic field. The orientation of the two magnetic layers can be opposite or the same to represent a high resistance state and a low resistance state, respectively.

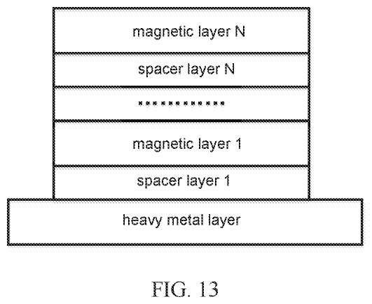

It can be understood that the spin valve of the present invention uses the stacked structure as shown in FIG. 12 to replace the antiferromagnetic layer and the magnetic layer 1 in the conventional spin valve structure. The magnetic orientation of the magnetic layer in contact with the non-magnetic spacer layer is fixed through combination of multiple spacer layers and magnetic layers, and properties such as the coercive force can be adjusted through repetition times. At the same time, the cost is low.

Based on the same inventive concept, the present invention also provides an embodiment of a racetrack memory, which comprises:

an antiferromagnetic structure layer, which comprises a plurality of stacked metal magnetic layer units, wherein each of the metal magnetic layer units comprises a spacer layer and a magnetic layer on a surface of the spacer layer; and

a heavy metal layer on a surface of the antiferromagnetic structure layer.

The film stack structure of the present invention can also be applied to a field of the racetrack memory. By applying current into the heavy metal layer deposited underneath, spin-orbit moments can be generated to move magnetic domain walls in the film layer. By changing the material and thickness of the spacer layer and the thickness of the magnetic layer, a strong Dzyaloshinskii-Moriya interaction (DMI) effect can be achieved, in such a manner that a size of magnetic domains and a moving speed of the magnetic domain wall can be adjusted. The diffusion of the heavy metal layer is isolated by the bottom spacer layer to improve the thermal stability, so as to be applied to the field of the racetrack storage, as shown in FIG. 13.

Based on the same inventive concept, the present invention also provides an embodiment of a skyrmion device, which comprises an antiferromagnetic structure layer, which comprises a plurality of stacked metal magnetic layer units, wherein each of the metal magnetic layer units comprises a spacer layer and a magnetic layer on a surface of the spacer layer.

With the development of big data, higher storage density and faster access speed are necessary. Because of small size, stability of topological protection, and being drivable by a very low-power spin-polarized current, skyrmion is generally considered to be an ideal information storage unit for the next generation of magnetic storage devices. By stacking the metal spacer layers and the magnetic layers, the skyrmion can be formed in the film layer, whose size and other characteristics can be adjusted by adjusting the thickness and material of the spacer layer and the magnetic layer. Therefore, the film structure described above can be applied to the skyrmion device.

In the prior art, the multilayer film structure “MgO/CoFeB/Mo/CoFeB/MgO” can also be used as a unit to form an artificial antiferromagnetic structure multilayer film, and a core structure of which is the two oxide barrier layers and the middle ferromagnetic-non-magnetic-ferromagnetic composite layer structure. In such structure, the multilayer film material with a perpendicular anisotropic artificial antiferromagnetic structure formed by a “CoFeB/MgO” system is a structure such as “MgO/CoFeB/Mo/CoFeB/MgO” obtained by inserting a core non-magnetic layer into the CoFeB layer of the “MgO/CoFeB/MgO” structure, in such a manner that the CoFeB layers located on both sides of the non-magnetic layer form an antiferromagnetic exchange coupling with perpendicular anisotropy, and the structure has strong thermal stability. However, such structure requires the oxide barrier layer to produce the system thermal stability, perpendicular magnetic anisotropy, and other advantages. After adding the oxide barrier layer, the spin diffusion depth limit not only makes the structure difficult to be applied to current-driven racetrack or skyrmion devices, but also affects resistance and performance of the magnetic tunnel junction.

Furthermore, in the prior art, a layered stack layer is also formed by alternating the magnetic sub-layers and the non-magnetic spacer layers. In such structure, a bottom layer is a seed layer formed by a material such as tantalum or magnesium. The structure comprises X+1 magnetic sub-layers and x non-magnetic spacer layers arranged alternately therewith, wherein X is 1-15. When the non-magnetic spacer layer is ruthenium, rhodium or iridium, the magnetic sublayer is preferably cobalt. However, the structure needs to expose the magnetic layers at both ends for the magnetic tunnel junction, and requires the bottom seed layer to form perpendicular magnetic anisotropy, which limits an application range of the structure. In addition, the non-magnetic spacer layer of the structure is made of ruthenium, rhodium or iridium, which has low thermal stability and is easy to diffuse, thus damaging the magnetic layer. At the same time, the non-magnetic layer is an alloy of Co or CoM, and the multilayer stack generates a large coercive force, making it difficult to be applied to current-driven magnetization flip devices.

Based on concept of the present invention, it is known that the above-mentioned problems in the prior art can be solved. First, when being applied to the racetrack memory or the skyrmion devices, the present invention has not oxide barrier layer, which means the structure can be applied to the current-driven racetrack memory or the skyrmion devices without affecting the resistance of the magnetic tunnel junction, and will not affect the performance of the magnetic tunnel junction. Second, there is no need to expose the magnetic layers at both ends, there is no need to form the perpendicular magnetic anisotropy in the bottom seed layer, and there is no limit to the application range of the structure. At the same time, the coercive force of the multilayer stack is small. The spacer layer can block the diffusion of the underlying heavy metal without affecting the spin diffusion, which can improve the flip efficiency and thermal stability of the current-driven magnetization flip device.

The embodiments of the present invention are described in a progressive manner. The same or similar parts of different embodiments can be referred to each other. Each embodiment focuses on the differences from other embodiments. In the description of the present invention, the terms “one embodiment”. “some embodiments”, “examples”, “specific example”, or “some examples” means that specific features, structures, materials, or characteristics described in conjunction with the embodiments or examples are included in at least one of the embodiments of the present invention.

According to the present invention, schematic representation of the above terms does not necessarily refer to the same embodiment or example. In addition, without contradicting each other, those skilled in the art may combine different embodiments or examples and features of the different embodiments or examples described in the present invention.

Finally, it should be noted that the above is only the embodiments of the present invention, and is not intended to be limiting. For those skilled in the art, various modifications and changes can be made to the embodiments of the present invention. Any modifications, equivalent replacements, improvements, and the like made within the spirit and principle of the embodiments should be included in the claimed scope of the embodiments of the present invention.

What is claimed is:

1. A magnetic tunnel junction reference layer, comprising:
an antiferromagnetic structure layer, which comprises a plurality of stacked metal magnetic layer units, wherein each of the metal magnetic layer units comprises a spacer layer and a magnetic layer on a surface of the spacer layer.

2. The magnetic tunnel junction reference layer, as recited in claim 1, further comprising:
a first oxide barrier layer on a first surface of the antiferromagnetic structure layer;
a second oxide barrier layer on a second surface of the antiferromagnetic structure layer facing away from the first oxide barrier layer; and
a first buffer layer located on a surface of the second oxide barrier layer facing away from the antiferromagnetic structure layer.

3. The magnetic tunnel junction reference layer, as recited in claim 2, further comprising:
a second buffer layer on a surface of the first buffer layer facing away from the second oxide barrier layer, and
a substrate on a surface of the second buffer layer facing away from the first buffer layer.

4. The magnetic tunnel junction reference layer, as recited in claim 2, further comprising:
a capping layer on a surface of the first oxide barrier layer facing away from the antiferromagnetic structure layer.

5. The magnetic tunnel junction reference layer, as recited in claim 2, wherein the first buffer layer and/or the spacer layer is selected from the group consisting of tantalum, tungsten, molybdenum, chromium, niobium, and ruthenium.

6. The magnetic tunnel junction reference layer, as recited in claim 1, wherein the magnetic layer is selected from the group consisting of CoFeB, CoFe, FeB, Co, Fe, and Heusler alloys.

7. The magnetic tunnel junction reference layer, as recited in claim 2, wherein the first oxide barrier layer and the second oxide barrier layer are selected from the group consisting of magnesium oxide, aluminum oxide, magnesium aluminum oxide, hafnium oxide, and tantalum oxide.

8. The magnetic tunnel junction reference layer, as recited in claim 1, wherein a thickness of the spacer layer is 0.1-1 nm.

9. A magnetic random access memory, comprising a plurality of storage units, wherein each of the storage units comprises a magnetic tunnel junction, and the magnetic tunnel junction comprises a magnetic tunnel junction reference layer as recited in claim 1.

10. A spin valve, comprising: a first magnetic layer, a non-magnetic spacer layer, a second magnetic layer and an antiferromagnetic structure layer, wherein the antiferromagnetic structure layer comprises a plurality of stacked metal magnetic layer units, wherein each of the metal magnetic layer units comprises a spacer layer and a magnetic layer on a surface of the spacer layer.

11. A racetrack memory, comprising:
an antiferromagnetic structure layer, which comprises a plurality of stacked metal magnetic layer units, wherein each of the metal magnetic layer units comprises a spacer layer and a magnetic layer on a surface of the spacer layer; and
a heavy metal layer on a surface of the antiferromagnetic structure layer.

12. A skyrmion device, comprising: an antiferromagnetic structure layer, which comprises a plurality of stacked metal magnetic layer units, wherein each of the metal magnetic layer units comprises a spacer layer and a magnetic layer on a surface of the spacer layer.
